(19) United States
(12) Patent Application Publication
(10) Pub. No.: US 2009/0220836 A1
(43) Pub. Date: Sep. 3, 2009

(54) PROCESS FOR THE MANUFACTURE OF AN ION-CONDUCTING POLYMER MEMBRANE FOR A FUEL CELL

(75) Inventors: Philippe Capron, Le Pin (FR); Jerome Delmas, Merignac (FR); Audrey Martinent, Grenoble (FR); Isabelle Rougeaux, Rives (FR)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Commissariat A L'Energie Atomique

(21) Appl. No.: 12/370,184

(22) Filed: Feb. 12, 2009

(30) Foreign Application Priority Data
Feb. 29, 2008 (FR) 08 01137

(51) Int. Cl. H01M 8/10; C23C 16/513

(52) U.S. Cl. 429/30; 427/569

(57) ABSTRACT

The invention relates to a process for the manufacture of an ion-conducting polymer membrane for a fuel cell and to a fuel cell core comprising such a membrane. It also relates to a fuel cell comprising such a membrane and/or such a cell core. The process of the invention comprises manufacturing an ion-conducting polymer membrane of a fuel cell by plasma chemical vapor deposition of at least two identical or different polymerizable monomers, each comprising: at least one polymerizable group, and at least one precursor group of the ion-conducting functional group chosen from the group formed by a phosphonyl ester, an acyl ester, a sulfonyl ester, a carbonyl halide or a thionyl halide.

### CROSS REFERENCE TO RELATED APPLICATION

This application claims priority to French Application No. 08 01137, filed Feb. 29, 2008.

### FIELD AND BACKGROUND OF THE INVENTION

The invention relates to a process for the manufacture of an ion-conducting polymer membrane for a fuel cell and to a fuel cell core comprising a membrane obtained by this process. It also relates to a fuel cell comprising such a membrane and/or such a cell core.

The core of a fuel cell is generally composed of a conducting membrane. The oxidation of the fuel takes place at the anode, at the interface between the electrode and the membrane. This reaction requires a catalyst which is composed of a noble or non-noble metal or metal alloy. The reduction of the oxidant takes place at the cathode, at the interface between the electrode and the membrane. This reaction also requires a catalyst, which is itself also composed of a noble or non-noble metal, or even of a metal complex.

The nature of the materials constituting this cell core depends mainly on the nature of the fuel and of the oxidant used but also on the type of conduction of the membrane.

The membrane can conduct cations or anions.

In the case of cations, it is generally the proton which passes in transit from the anode to the cathode, as for the Proton Exchange Membrane Fuel Cell (PEMFC) and the Direct Methanol Fuel Cell (DMFC).

In the case of anions, it is the hydroxonium anion which passes in transit from the cathode to the anode. This type of cell is commonly known as Solid Alkaline Fuel Cell (SAFC).

The membrane has ionic groups with an opposite charge to that of the ion to be transported. Specifically, in the case of proton transportation, the membrane has acid functional groups of sulfonic, carboxylic or phosphonic type. In the case of transportation of OH⁻ ions, the membrane has functional groups of quaternary ammonium type.

The most widely used process for manufacturing a cell core in a cell architecture consists in using an electrode-membrane-electrode assembly made by hot bonding of a membrane and two electrodes formed beforehand. This technique is commonly used to produce a cell core stack with bipolar plates in order to form a stack.

Another process consists in juxtaposing cell cores on a substrate in order to form a planar architecture. One of the technological solutions which makes it possible to obtain such an architecture consists in creating the various components of the cell core in situ by depositions of different materials. The anode catalyst is deposited on the substrate by the wet route (spraying an “ink” comprising the catalyst, the solvent and a binder) or by the dry route (plasma vapor deposition or chemical vapor deposition). The membrane is subsequently formed from an ionomer solution (mixture of an ion-conducting polymer and a solvent). The cathode is subsequently produced in the same way as the anode.

The use of an ionomer solution is relatively easy and makes it possible to obtain membranes of very good quality. However, in the case of complex architecture or of solvent-sensitive substrate, it is very difficult to obtain a film which perfectly conforms to the surface of the substrate.

In order to overcome these difficulties, novel processes have been developed, mainly by the dry route, that is to say without using solvent. These novel processes are based on the principle of depositions by vacuum technology. These technologies consist in generating a membrane at the surface of the substrate or the electrode from a precursor, generally a gaseous precursor, in a vacuum chamber. The membrane thus obtained exhibits a uniform thickness, whatever the geometry of the substrate.

Thus, U.S. Pat. No. 6,010,798 describes the preparation of a proton-conducting membrane by vacuum technology of Plasma Enhanced Chemical Vapor Deposition (PECVD) type.

This technology consists in placing, in a vacuum chamber, the substrate on which the membrane has to be produced. A low or high vacuum is subsequently established and various chemical precursors are injected. The precursors are composed of aliphatic or fluorocarbon chains or of sulfonated or nonsulfonated monomers. The ionic functional group is introduced either by virtue of the use of a monomer carrying an ionic group or by using a gas of SO₂ or SO₃ or trifluoromethanesulfonic type or also phosphonic acids.

The plasma applied to the mixture enables to bring energy in order to generate chemical reactions which make it possible to obtain a network which is sometimes incorrectly referred to as a polymer system.

However, this process, although it makes it possible effectively to obtain a uniform deposited layer which conforms to the surface of the substrate, has very major disadvantages.

Specifically, the energy brought by the plasma brings about strong crosslinking of the deposited layer. But, the membrane, in order to conduct protons, has to be able to swell in the presence of water. This swelling is natural and is related to the affinity between the ionic functional groups and the water. The conduction of the membrane requires, on the one hand, the presence of water and, on the other hand, the presence of ionic functional groups. Significant crosslinking of the membrane limits this swelling and consequently results in a low conductivity. Finally, the energy contributed by the plasma decomposes the organic molecules and more particularly the S—O bonds. Consequently, it is very difficult to accurately and reproducibly control the level of sulfonic functional groups in these deposited layers.

U.S. Pat. No. 4,225,647 describes a vacuum process which does not use plasma. This patent does not describe the manufacture of an ion-conducting membrane for a fuel cell but a process for the deposition of poly-para-xylylene on an object. The technique described in this patent is similar to Vapor Deposition Polymerization (VDP) and consists in subliming a monomer which is subsequently activated thermally at temperatures of greater than 500° C. in order to bring about polymerization during the condensation of the monomer on the substrate.

By this technique, the chemical structure is well controlled and the polymer formed is noncrosslinked. In this document, the ionic functional group is incorporated by posttreatment of the film, that is to say in a second stage and not in situ.

This is because, as poly-para-xylylene comprises aromatic rings, it is possible to introduce sulfonic functional groups by treatment of the film with a concentrated acid solution. However, this treatment, on the other hand, causes cleavage of chains of the polymer and, on the other hand, brings about a sulfonation which is difficult to control.

The properties of the membrane are consequently very mixed. This document evokes the possibility of using monomers which have been functionalized beforehand, in this instance by acids. However, this functionalization does not withstand the high temperatures necessary for the activation of the monomer in order to provide for the polymerization thereof. Moreover, these functionalized monomers cannot be sublimed as they decompose before sublimation. This is because the existence of strong molecular interactions of ionic type and of hydrogen bond type limits the ability of these molecules to evaporate.

### SUMMARY OF THE INVENTION

The invention aims at overcoming the disadvantages of the processes of the prior art by providing a process which does not use a solvent and which makes it possible to obtain a noncrosslinked ion-conducting membrane which perfectly matches the shape of a substrate of complex (3D) geometry and has very good ion-conducting properties.

To this end, the invention provides a process in which use is made of one or more polymerizable monomers which can be sublimed or evaporated under vacuum, at least two of the monomers already carrying a precursor functional group of the ion-conducting functional group.

To this end, the invention provides a process for the manufacture of an ion-conducting polymer membrane for a fuel cell, which comprises a step of plasma chemical vapor deposition of at least two identical or different polymerizable monomers, each comprising:
at least one polymerizable group, and
at least one precursor group of the ion-conducting functional group chosen from the group formed by a phosphonyl ester, an acyl ester, a sulfonyl ester, a carbonyl halide or a thionyl halide.

In a first embodiment, said at least two monomers are identical and carry a group which can polymerize by radical polymerization.

In this case, preferably, said polymerizable group is a glycidyl or ethylenic group.

In a second embodiment, said at least two monomers are different from one another, at least one of the monomers carrying two polymerizable groups which are different from the two polymerizable groups of the other monomer, while being polymerizable by polycondensation with these two polymerizable groups of the other monomer.

In this case, preferably, the polymerizable groups are chosen from an acid group, an anhydride group, an alcohol group, a halide group, a urea group and an amine group.

In all the embodiments of the invention, each monomer is composed of an aromatic or aliphatic chain carrying said at least one polymerizable group and said at least one precursor group of the ion-conducting functional group.

The invention also provides a fuel cell core comprising a membrane obtained by the process of the invention.

It also provides a fuel cell comprising a membrane obtained by the process of the invention and also a fuel cell comprising a cell core according to the invention.

### MORE DETAILED DESCRIPTION

A better understanding of the invention will be obtained and other features and advantages of the invention will become more clearly apparent on reading the explanatory description which follows.

The ion-conducting membrane for a fuel cell of the invention is manufactured from monomers which carry a polymerizable functional group. The monomers can all have identical polymerizable functional groups, in which case the polymerizable functional group is a functional group which can polymerize by radical polymerization. Preferably, this polymerizable functional group is of the glycidyl or ethylenic type.

They can also have different polymerizable functional groups. In this case, the polymerization takes place by polycondensation of the polymerizable functional groups of one with the polymerizable functional groups of the other. The polymerizable functional groups in this case are preferably acid, anhydride, alcohol, amine, halide or urea functional groups.

A polymer membrane will be obtained by polymerization of these monomers.

However, in order to obtain an ion-conducting polymer membrane, the invention uses monomers which, in addition to the polymerizable functional group, are functionalized by sulfonyl ester functional groups of formula SO₃R, acyl ester functional groups of formula COOR, phosphonyl ester functional groups of formula PO(OR)₂, carbonyl halide functional groups of formula COX or thionyl halide functional groups of formula SO₂X′ and not, as in the prior art, functionalized by acid functional groups.

In the preceding formulae, R can be a polyphatic aromatic chain and also a derivative of the latter, and X′ represents a halide, such as a chlorine.

These functional groups of ester or halide type described above do not exhibit strong molecular interactions and can consequently be sublimed or evaporated. Once the polymer has been obtained, the functional groups of ester or halide type described above are converted to their acid form by hydrolysis in water or in an acidic or basic solution. The polymer obtained then becomes ion-conducting.

Thus, the monomers used in the invention have one of the following formulae:

Formula I:

Z-A-Y 1)

in which:
Z is a functional group which can polymerize by radical polymerization of glycidyl or ethylenic type,
Y is a precursor of the ionic functional group as described above, and
A is an aliphatic or aromatic chain or a derivative of such a chain.

Advantageously, the precursor of the ionic functional group will be of SO₃SiR′₃ type with R′ being an aliphatic or aromatic group. This is because this type of precursor can be very readily hydrolyzed by simple contact with water.

The monomer of formula I can be evaporated alone in a plasma chamber or with other functionalized or nonfunctionalized monomers. A radical polymerization initiator can be added, such as azobisisobutyronitrile (AIBN), benzoyl peroxide, tert-butyl peroxide and more generally an organic peroxide.

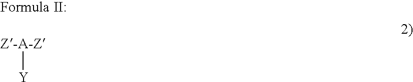

in which:
A is an aromatic or aliphatic chain or a derivative of 20 such a chain,
Z′ is a functionality which can polymerize by polycondensation, such as an acid, an anhydride, an alcohol, an amine, a halide or a urea functional group, and
Y is a precursor of the ionic functional group, as described above.

In the case of the use of such a monomer of formula II, it is necessary to use, at the same time, a monomer of the following formula III:

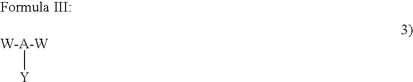

in which W is a different polymerizable chemical functional group from Z′ which is capable of reacting with the polymerizable functional group Z′ of the polymer of formula II by polycondensation to form a polymer.

In this monomer of formula III, Y can be a functionality identical to the functionality Y described above or may not be present.

Thus, in the invention, the ion-conducting polymer membrane is manufactured by vacuum thermal coevaporation. The solid or liquid monomers are placed in crucibles in the vacuum chamber which can fall to a pressure of 10⁻⁶ bar. The substrate to be coated, on which the membrane is formed, is placed on a rotating substrate holder which is or is not heated according to the monomers used. The substrate is generally the electrode. It can thus be made of a stack of layers. The substrate comprises, for example, the catalyst, such as platinum. Preferably, the substrate is made of silicon or of carbon, which is advantageously porous. Most preferably, the substrate is made of silicon, which is preferably porous. Once the vacuum has been achieved, by virtue of the use of a backing pump and of a high-vacuum pump of turbomolecular type, the crucibles comprising the monomers are heated by virtue of a Joule effect source or a source of organic or OLED type. The covers of the substrates and of the sources are closed. Once the temperatures have been reached, the covers of the sources are opened in order to measure the vapor flow of each monomer using quartz microbalances. The evaporation temperatures of the monomers are corrected by means of the temperatures of the sources, in order to obtain the vapor flow appropriate for each monomer. The cover of the substrate is subsequently opened and the monomers will condense and polymerize on the substrate. A quartz balance measures the weight and the thickness of the deposited layer.

Several monomers can thus be evaporated or sublimed simultaneously. The chamber can also comprise additional components capable of contributing to improving the polymerization and in particular radical polymerizations of the monomers, such as a UV lamp or filaments heated to a high temperature in the case of the use of radical polymerization initiator.

The polymers obtained can be of polystyrene, polyimide, polyamide, polyfurfuryl alcohol, polyacrylate, polyacrylamide, polycarbazole, polyurea, polyurethane, polyester, polyepoxy or polyphenylquinoxaline type, and the like, comprising at least one precursor functional group of the ion-conducting functional group.

Subsequently, the membrane formed is used to manufacture a fuel cell core. The cell core is itself used to manufacture a fuel cell.

In order to achieve a better understanding of the invention, an embodiment thereof will now be described as a purely illustrative and nonlimiting example.

### EXAMPLE

1 g of phenylethylenesulfonate is placed in a crucible, 1 g of styrene is placed in another crucible and 200 mg of tert-butyl peroxide are placed in a third crucible in the vacuum thermal evaporation chamber.

The substrate is a silicon disk with a diameter of 10 cm.

The covers of the sources and of the substrates are in the closed position. The vacuum is brought down to a pressure of 10⁻⁵ bar using a backing pump and a turbomolecular pump. Once the vacuum has been achieved, the crucibles are heated to respective temperatures of 60° C., 70° C. and 40° C. using a source of OLED type. Once the temperatures have been reached, the covers of the sources are opened in order to measure the flow in mol/min in each of the compounds. The flows are subsequently adjusted by regulating the temperature in order to obtain a flow of 0.1 μg/cm²/s of phenylethylenesulfonate, of 0.15 μg/cm²/s of styrene and of 0.01 μg/cm²/s of tert-butyl peroxide.

The flows are measured using quartz balances and correspond to what is deposited on the substrate as the quartz balances were calibrated beforehand relative to the source and to the substrate via weight measurements.

Once the flow adjustments have been carried out, the cover of the substrate is subsequently opened in order to carry out the deposition on the silicon substrate. After approximately 1 hour, a polymer film having a thickness of the order of 5 μm is obtained. The covers of the sources are closed again and the pressure is brought back to atmospheric pressure.

The film is subsequently hydrolyzed in a 1 mol/l hydrochloric acid solution at 60° C. for 4 hours.

The proton conductivity of the membrane is subsequently measured by measurement of impedance. The conductivity is evaluated at 8×10⁻³ S/cm.

What is claimed is:

1. A process for the manufacture of an ion-conducting polymer membrane of a fuel cell, which comprises a step of plasma chemical vapor deposition of at least two identical or different polymerizable monomers, each comprising:
at least one polymerizable group, and
at least one precursor group of the ion-conducting functional group chosen from the group formed by a phosphonyl ester, an acyl ester, a sulfonyl ester, a carbonyl halide or a thionyl halide.

2. The process as claimed in claim 1, wherein said at least two monomers are identical and carry a group which can polymerize by radical polymerization.

3. The process as claimed in claim 2, wherein said polymerizable group is a glycidyl or ethylenic group.

4. The process as claimed in claim 1, wherein said at least two monomers are different from one another, at least one of the monomers carrying two polymerizable groups which are different from the two polymerizable groups of the other monomer, while being polymerizable by polycondensation with these two polymerizable groups of the other monomer.

5. The process as claimed in claim 4, wherein the polymerizable groups are chosen from an acid group, an anhydride group, an alcohol group, a halide group, a urea group and an amine group.

6. The process as claimed in claim 1, wherein each monomer is composed of an aromatic or aliphatic chain carrying said at least one polymerizable group and said at least one precursor group of the ion-conducting functional group.

7. A fuel cell core comprising a membrane obtained by the process as claimed in claim 1.

8. A fuel cell comprising a membrane obtained by the process as claimed in claim 1.

9. A fuel cell comprising a cell core as claimed in claim 7.
